(19) United States
(12) Patent Application Publication
(10) Pub. No.: US 2023/0395655 A1
(43) Pub. Date: Dec. 7, 2023

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Shih-Cheng Chen, New Taipei City (TW); Zhi-Chang Lin, Hsinchu County (TW); Jung-Hung Chang, Changhua County (TW); Chien-Ning Yao, Hsinchu (TW); Tsung-Han Chuang, Tainan City (TW); Kuo-Cheng Chiang, Hsinchu County (TW); Chih-Hao Wang, Hsinchu County (TW)

(73) Assignee: Taiwan Semiconductor Manufacturing Company, Ltd., Hsinchu (TW)

(21) Appl. No.: 17/832,681

(22) Filed: Jun. 5, 2022

(51) Int. Cl. H01L 29/06; H01L 29/417; H01L 29/423; H01L 29/786; H01L 21/02; H01L 21/311; H01L 29/66

(52) U.S. Cl. CPC H01L 29/0649; H01L 29/0665; H01L 29/41733; H01L 29/42392; H01L 29/78696; H01L 21/0259; H01L 21/31111; H01L 29/66553; H01L 29/66742

(57) ABSTRACT

Provided are a semiconductor device and a method of forming the same. The semiconductor device includes at least two active strip regions, a hybrid fin structure, and a gate stack. The hybrid fin structure is disposed between the at least two active strip regions. The gate stack is across the at least two active strip regions and the hybrid fin structure. A portion of the hybrid fin structure exposed by the gate stack is free of a high dielectric constant material.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, multi-gate devices have been introduced to replace planar transistors. However, there are quite a few challenges to be handled for the multi-gate technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a simplified top-down layout view of a semiconductor device in accordance with some embodiments.

FIG. 2 is a flow chart of a method of forming a semiconductor device in accordance with some embodiments.

FIG. 3, FIG. 4, FIG. 5, FIG. 6, FIG. 7, and FIG. 8 are cross-sectional views of a semiconductor device formed according to the method of FIG. 2, along a plane substantially parallel to a plane defined by section I-I′ of FIG. 1.

FIG. 9, FIG. 10, FIG. 11, and FIG. 12 are isometric views of a semiconductor device formed according to the method of FIG. 2.

FIG. 13A, FIG. 14A, FIG. 15A, FIG. 16A, FIG. 17A, and FIG. 18A are cross-sectional views of a semiconductor device in FIG. 12 taken along the line A-A in accordance with some embodiments.

FIG. 13B, FIG. 14B, FIG. 15B, FIG. 16B, FIG. 17B, and FIG. 18B are cross-sectional views of a semiconductor device in FIG. 12 taken along the line B-B in accordance with some embodiments.

FIG. 13C, FIG. 14C, FIG. 15C, FIG. 16C, FIG. 17C, and FIG. 18C are cross-sectional views of a semiconductor device in FIG. 12 taken along the line C-C in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to semiconductor devices and the fabrication thereof, and more particularly to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel (e.g., single nanosheets) or any number of channels. One of ordinary skill may recognize other examples of semiconductor devices that may benefit from aspects of the present disclosure.

In accordance with some embodiments, a gate stack is across at least two active strip regions and a hybrid fin structure between the at least two active strip regions. As technology nodes shrink, the hybrid fin structure with a high-K dielectric layer may effectively prevent the undesirable lateral merging of the source/drain features formed on adjacent active strip regions. In this case, the high-K dielectric layer may cause parasitic coupling between the metal gate and adjacent source/drain contact plug, thereby degrading device performance. It should be noted that, in the present embodiment, the high-K dielectric layer of the hybrid fin structure uncovered by the gate stack suffers from an anisotropic etching and a lateral trimming, so that a portion of the hybrid fin structure exposed by the gate stack is free of a high dielectric constant material. In such embodiment, the undesirable parasitic capacitance between the metal gate and the adjacent source/drain contact plug may be reduced, thereby enhancing the device performance.

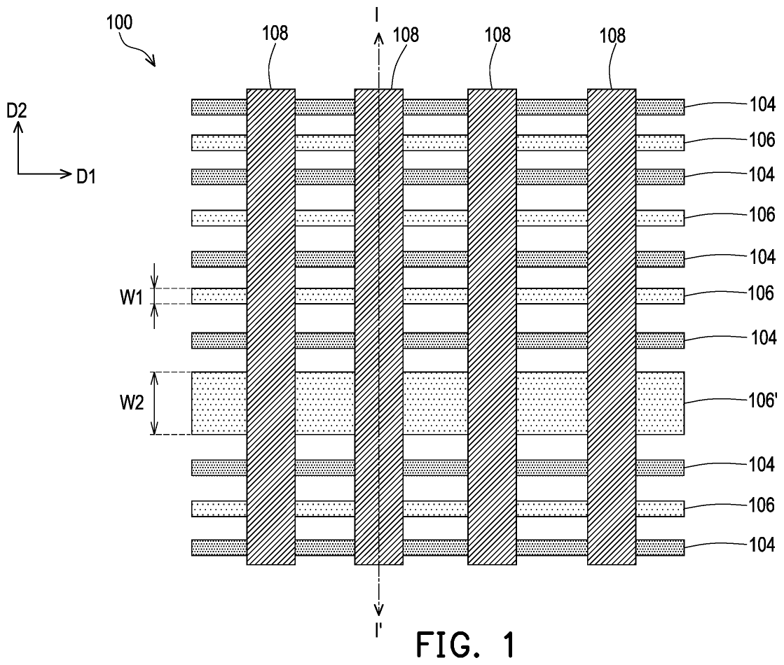

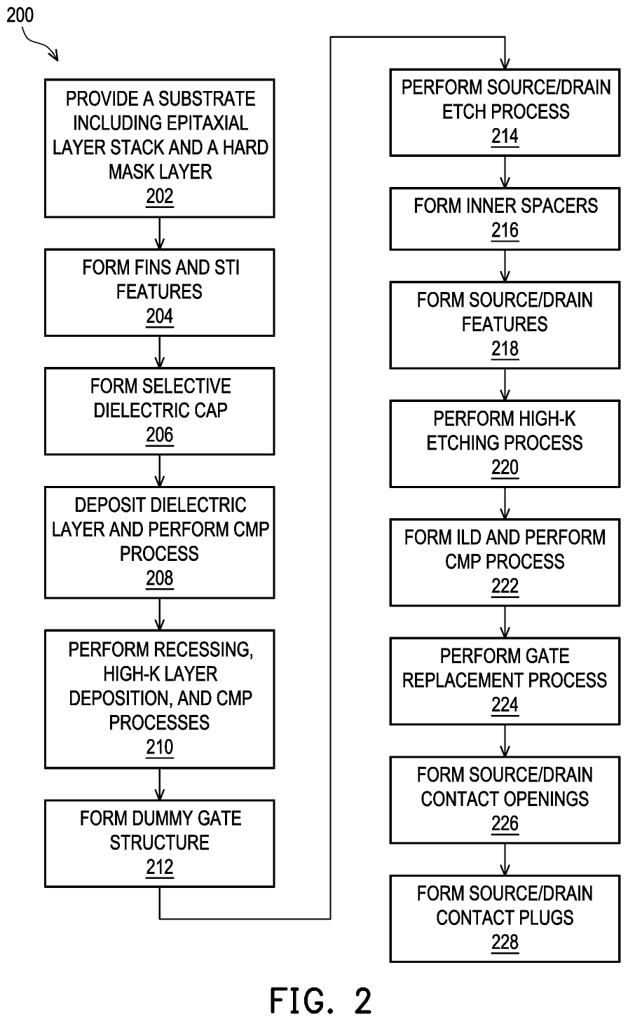

FIG. 1 provides a simplified top-down layout view of a semiconductor device 100 in accordance with some embodiments. In some embodiments, the semiconductor device 100 may include FinFETs, GAA transistors, or other types of multi-gate devices. The semiconductor device 100 may include a plurality of fin elements 104 extending from a substrate, a plurality of hybrid fins 106 and 106′, and a plurality of gate structures 108. In some embodiments, the fin elements 104 and the hybrid fins 106 and 106′ extend along a first direction D1 (e.g., X direction), and arranged alternately along a second direction D2 (e.g., Y direction). Specifically, one of the hybrid fins 106 and 106′ may be sandwiched between adjacent two fin elements 104. In some embodiments, each fin element 104 may be referred to an active strip region which includes a semiconductor nanosheet stack for GAA device. In some embodiments, the gate structures 108 extend along the second direction D2, across the fin elements 104 and the hybrid fins 106 and 106′, and arranged alternately along the first direction D1. Channel regions of the semiconductor device 100, which may include a plurality of semiconductor channel layers (e.g., when the semiconductor device 100 includes a GAA transistor), are disposed within the fins 104, underlying the gate structures 108, along a plane substantially parallel to the first direction D1. In some embodiments, source/drain regions may also be formed in contact with opposing ends of the channel regions of the fin elements 104. In some embodiments, sidewall spacers may also be formed on sidewalls of the gate structures 108. As shown in FIG. 1, the hybrid fins 106 may have a width W1 less than a width W2 of the hybrid fins 106′. However, the embodiments of the present disclosure are not limited thereto. In other embodiments, configurations of widths for each of the hybrid fins 106 and 106′ may be adjusted by the design needs. Various other features of the semiconductor device 100 are discussed in more detail below with reference to the method of FIG. 2.

FIG. 2 is a flow chart of a method 200 of forming a semiconductor device 300 in accordance with some embodiments. As discussed above, the semiconductor device 300 may include a multi-gate device, such as a FinFET, a GAA device, or other devices having gate structures formed on at least two-sides of a channel region and may include devices having channel regions formed as nanosheet channel(s), nanowire channel(s), bar-shaped channel(s), and/or other suitable channel configurations. The method 200 is discussed below with reference to a GAA device having a channel region that may be referred to as a nanowire and/or nanosheet and which may include various geometries (e.g., cylindrical, bar-shaped) and dimensions. However, it will be understood that aspects of the method 200, including the disclosed hybrid fins, may be equally applied to other types of multi-gate devices (e.g., such as FinFETs or devices including both GAA devices and FinFETs) without departing from the scope of the present disclosure. It is understood that the method 200 includes steps having features of a complementary metal-oxide-semiconductor (CMOS) technology process flow and thus, are only described briefly herein. Also, additional steps may be performed before, after, and/or during the method 200.

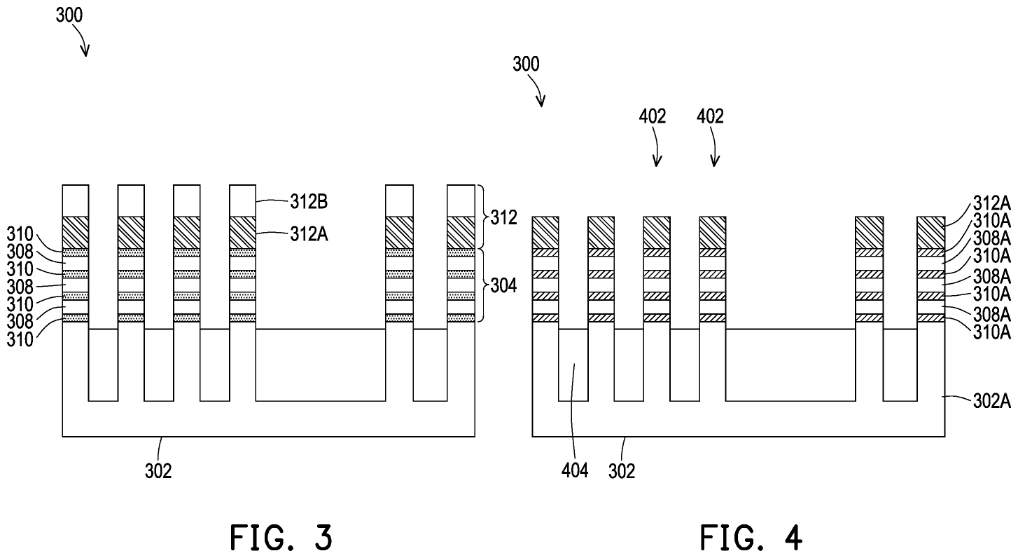

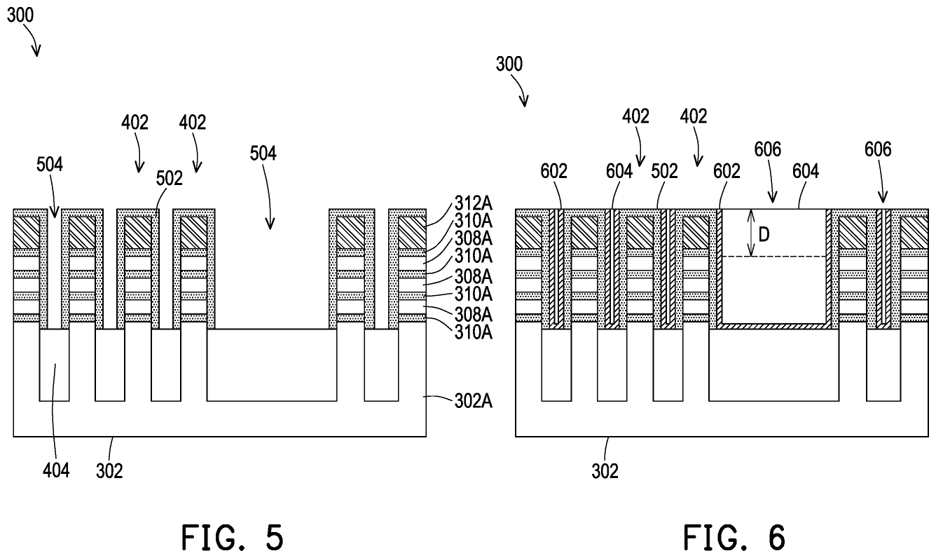

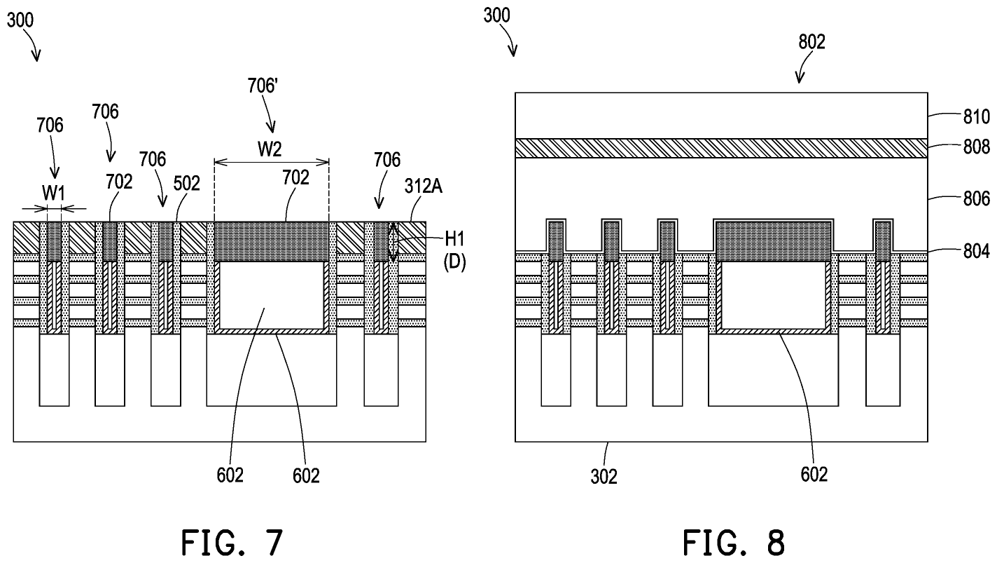

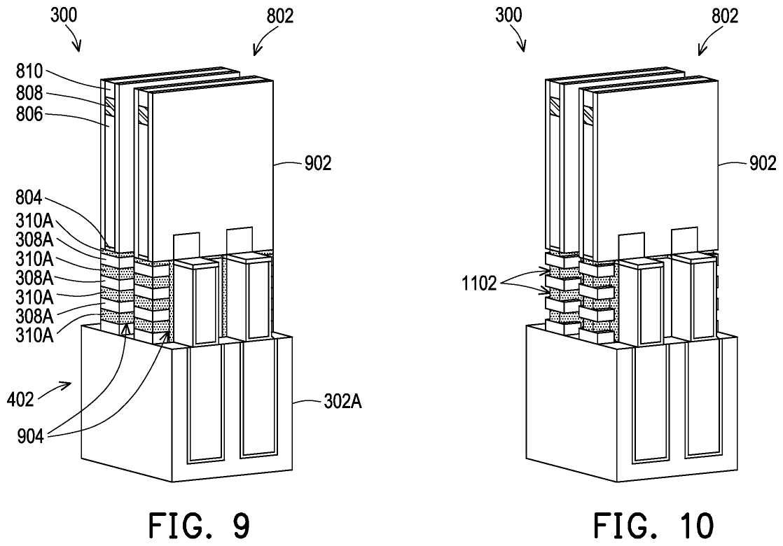

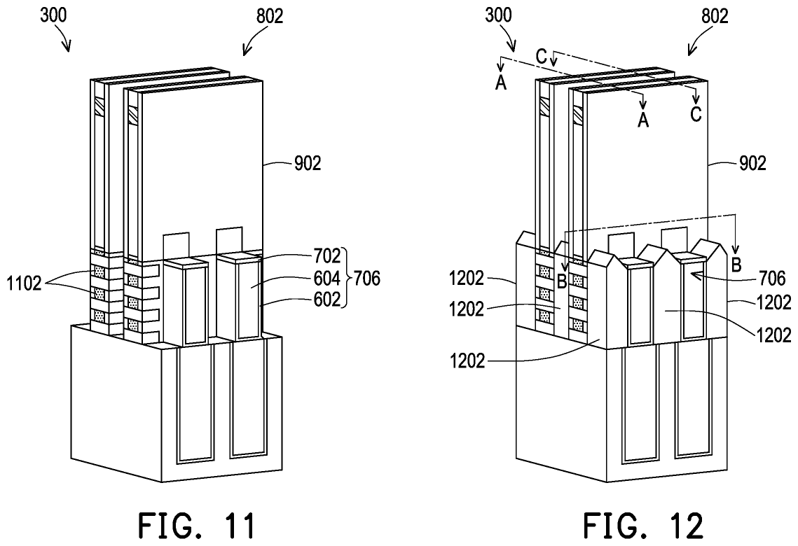

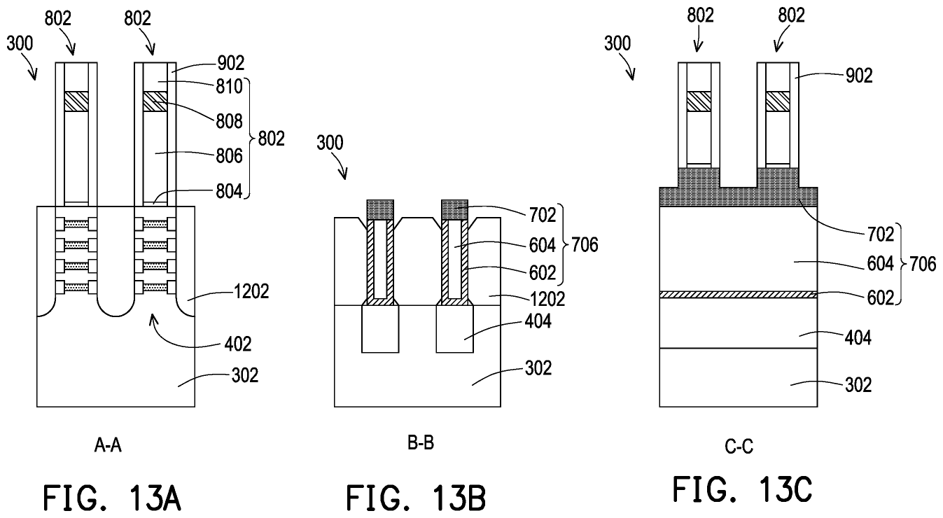

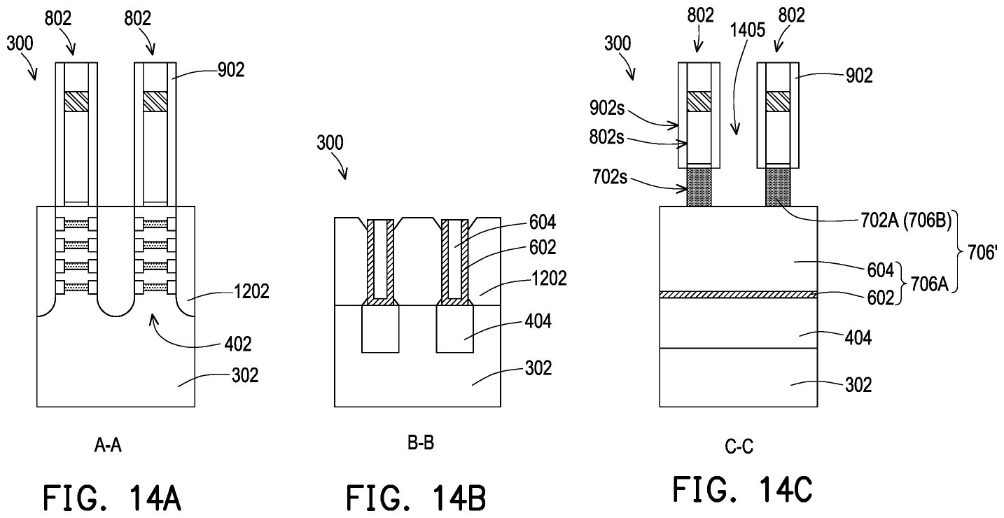

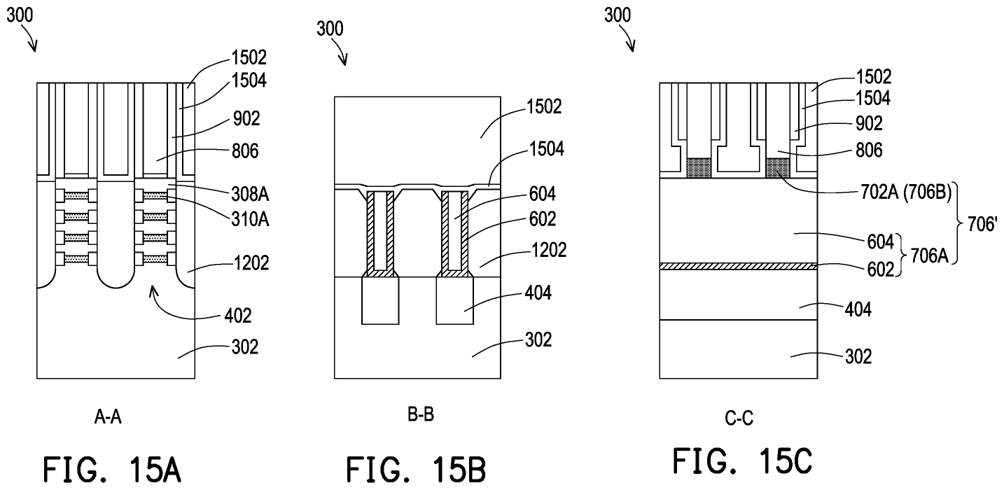

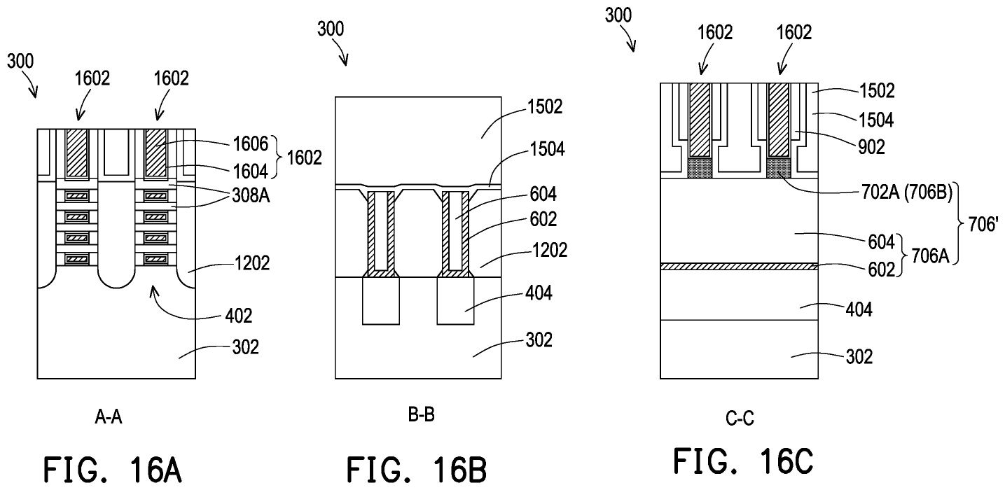

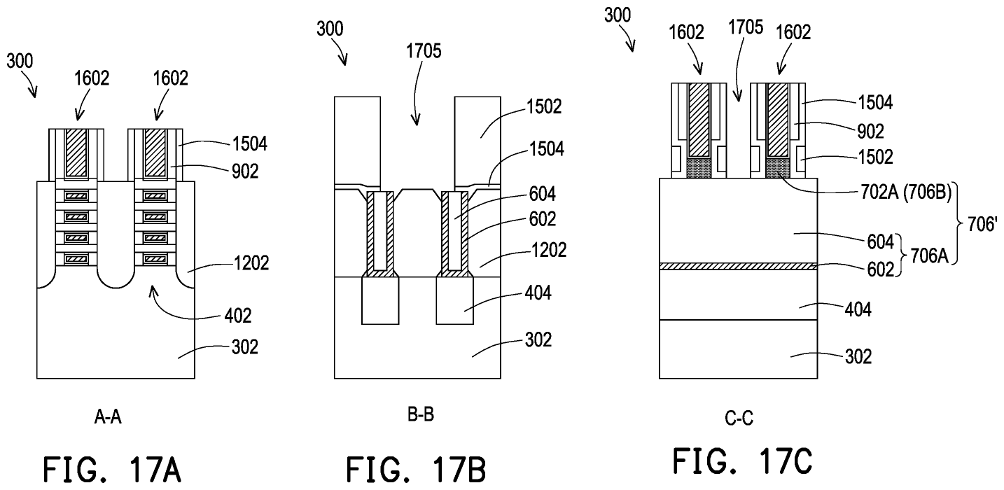

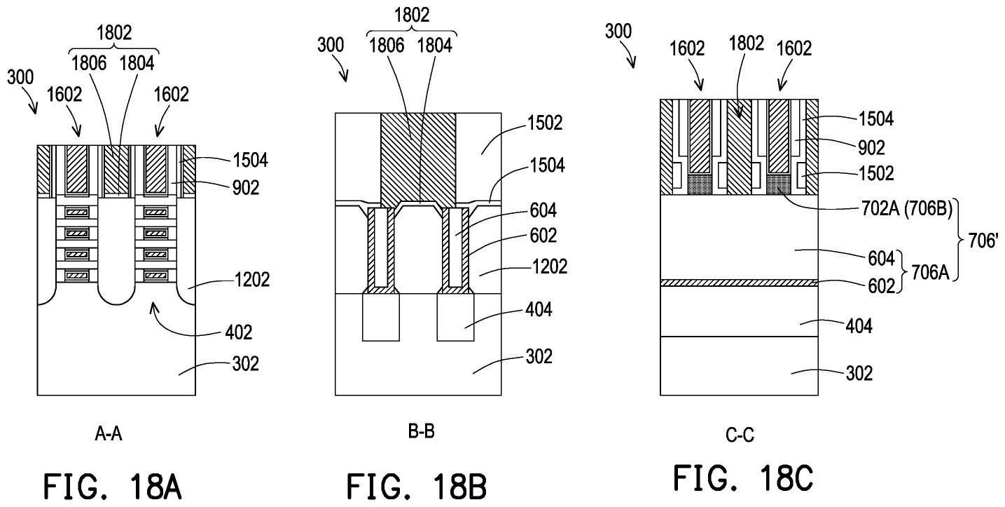

The method 200 is described with reference to various figures which illustrate different views of exemplary embodiments of the semiconductor device 300 according to various stages of the method 200 of FIG. 2. For example, FIG. 3, FIG. 4, FIG. 5, FIG. 6, FIG. 7, and FIG. 8 provide cross-sectional views of an embodiment of the semiconductor device 300 along a plane substantially parallel to a plane defined by section I-I′ of FIG. 1. FIG. 9, FIG. 10, FIG. 11, and FIG. 12 are isometric views of an embodiment of the semiconductor device 300 according to various stages of the method 200 of FIG. 2. FIG. 13A, FIG. 14A, FIG. 15A, FIG. 16A, FIG. 17A, and FIG. 18A are cross-sectional views of the semiconductor device 300 in FIG. 12 taken along the line A-A in accordance with some embodiments. FIG. 13B, FIG. 14B, FIG. 15B, FIG. 16B, FIG. 17B, and FIG. 18B are cross-sectional views of the semiconductor device 300 in FIG. 12 taken along the line B-B in accordance with some embodiments. FIG. 13C, FIG. 14C, FIG. 15C, FIG. 16C, FIG. 17C, and FIG. 18C are cross-sectional views of the semiconductor device 300 in FIG. 12 taken along the line C-C in accordance with some embodiments.

Further, the semiconductor device 300 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 300 includes a plurality of semiconductor devices (e.g., transistors), including P-type FETs, N-type FETs, etc., which may be interconnected. Moreover, it is noted that the process steps of the method 200, including any descriptions given with reference to the figures are merely exemplary and are not intended to be limiting beyond what is specifically recited in the claims that follow.

The method 200 begins at block 202 where a substrate including an epitaxial layer stack and a hard mask (HM) layer is provided. Referring to the example of FIG. 3, in an embodiment of block 202, a substrate 302 including an epitaxial layer stack 304 is provided. In some embodiments, the substrate 302 may be a semiconductor substrate such as a silicon substrate. The substrate 302 may include various layers, including conductive or insulating layers formed on a semiconductor substrate. The substrate 302 may include various doping configurations depending on design requirements as is known in the art. The substrate 302 may also include other semiconductors such as germanium, silicon carbide (SiC), silicon germanium (SiGe), or diamond. Alternatively, the substrate 302 may include a compound semiconductor and/or an alloy semiconductor. Further, the substrate 302 may optionally include an epitaxial layer (epi-layer), may be strained for performance enhancement, may include a silicon-on-insulator (SOI) structure, and/or have other suitable enhancement features.

In some embodiments, the epitaxial layer stack 304 includes epitaxial layers 310 having a first composition interposed by epitaxial layers 308 having a second composition. In an embodiment, the epitaxial layers 310 having the first composition are SiGe and the epitaxial layers 308 having the second composition are silicon (Si). However, other embodiments are possible including those that provide for a first composition and a second composition having different oxidation rates and/or etch selectivity. For example, in some embodiments, either of the epitaxial layers 308, 310 of the first composition or the second composition may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlinAs, AlGaAs, InGaAs, GaInP, and/or GaInAsP, or combinations thereof. By way of example, epitaxial growth of the epitaxial layers 308, 310 of the first composition or the second composition may be performed by a molecular beam epitaxy (MBE) process, a metalorganic chemical vapor deposition (MOCVD) process, and/or other suitable epitaxial growth processes. It is also noted that while the epitaxial layers 308, 310 are shown as having a particular stacking sequence, where an epitaxial layer 310 is the topmost layer of the epitaxial layer stack 304, other configurations are possible. For example, in some cases, an epitaxial layer 308 may alternatively be the topmost and/or the bottommost layer of the epitaxial layer stack 304, so that the stacking sequence of the epitaxial layer stack 304 is 308/310/308/310/308/310/308. Stated another way, the order of growth for the epitaxial layers 308, 310, and thus their stacking sequence, may be switched or otherwise be different than what is shown in the figures, while remaining within the scope of the present disclosure.

After forming the epitaxial layer stack 304, a hard mask (HM) layer may be formed over the device 300, where the HM layer may be patterned (e.g., using lithography and etching processes) to form a patterned HM layer 312. The patterned HM layer 312 may, in various examples, define a pattern used for subsequent formation of active fins and hybrid fins, as discussed below. In some embodiments, the patterned HM layer 312 includes a nitride layer 312A (e.g., a pad nitride layer that may include Si₃N₄) and an oxide layer 312B (e.g., a pad oxide layer that may include SiO₂) formed over the nitride layer 312A. In some examples, the oxide layer 312B may include thermally grown oxide, CVD-deposited oxide, and/or ALD-deposited oxide, and the nitride layer 312A may include a nitride layer deposited by CVD or other suitable technique. Generally, in some embodiments, the patterned HM layer 312 may include a nitride-containing material deposited by CVD, ALD, PVD, or other suitable process.

After forming the patterned HM layer 312, the method 200 proceeds to block 204 where fins and shallow trench isolation (STI) features are formed. Referring to the example of FIGS. 3 and 4, in an embodiment of block 204, fins 402 may be fabricated by etching the epitaxial layer stack 304 and the substrate 302 by using the patterned HM layer 312 as a mask. In various examples, the mask (e.g., the patterned HM layer 312) may be used to protect regions of the substrate 302, and layers formed thereupon, while an etch process forms trenches in unprotected regions through the through the epitaxial layer stack 304, and into the substrate 302, thereby leaving the plurality of fins 402 extending from the substrate 302. In some embodiments, the fins 402 may be referred to as active fins. The trenches may be etched by using a dry etch (e.g., reactive ion etching), a wet etch, and/or other suitable processes.

In various embodiments, each of the fins 402 includes a substrate portion 302A formed from the substrate 302, epitaxial layer portions 310A formed from the epitaxial layers 310, epitaxial layer portions 308A formed from the epitaxial layers 308, and the patterned HM layer 312 including the nitride layer 312A. In some embodiments, the oxide layer 312B of the patterned HM layer 312 may be removed (e.g., by a CMP process) prior to and/or during formation of the fins 402. In various embodiments, the epitaxial layer portions 308A, or portions thereof, may form a channel region of a GAA transistor of the device 300. For example, the epitaxial layer portions 308A may be referred to as nanosheets or nanowires that are used to form a channel region of a GAA device. These nanosheets or nanowires may also be used to form portions of the source/drain features of the GAA device, as discussed below. In embodiments where a FinFET is formed, each of the fins 402 may alternatively include an epitaxial layer of a uniform composition formed over the substrate portion, or each of the fins 402 may include a portion of the patterned substrate without an additional epitaxial layer formed over the substrate portion.

It should be noted that while the fins 402 are illustrated as including four layers of the epitaxial layer portions 310A and three layers of the epitaxial layer portions 308A, this is for illustrative purposes only and not intended to be limiting beyond what is specifically recited in the claims. It can be appreciated that any number of epitaxial layers can be formed, where for example, the number of epitaxial layers depends on the desired number of channels regions for the GAA device.

In some embodiments, the epitaxial layer portions 310A have a thickness range of about 6-15 nanometers (nm). In some cases, the epitaxial layer portions 308A have a thickness range of about 4-8 nm. As noted above, the epitaxial layer portions 308A may serve as channel region(s) for a subsequently-formed multi-gate device (e.g., a GAA device) and its thickness may be chosen based on device performance considerations. The epitaxial layer portions 310A may serve to define a gap distance between adjacent channel region(s) for the subsequently-formed multi-gate device and its thickness may also be chosen based on device performance considerations.

After forming the fins 402, and in a further embodiment of block 204, the trenches interposing the fins 402 may be filled with a dielectric material to form STI features interposing the fins 402, where the STI features are subsequently recessed to form the STI features 404. In some examples, the recessing to form the STI features 404 may expose portions of the nitride layer 312A, sidewalls of the epitaxial layer portions 308A, sidewalls of the epitaxial layer portions 310A, and a portion of sidewalls of the substrate portions 302A. In some embodiments, the dielectric material used to fill the trenches, and thus the STI features 404, may include SiO₂, silicon nitride, silicon oxynitride, fluorine-doped silicate glass (FSG), a low-K dielectric, combinations thereof, and/or other suitable materials known in the art. In various examples, the dielectric material may be deposited by a CVD process, a subatmospheric CVD (SACVD) process, a flowable CVD process, an ALD process, a PVD process, and/or other suitable process.

The method 200 then proceeds to block 206 where a selective dielectric cap layer is formed. Referring to the example of FIGS. 4 and 5, in an embodiment of block 206, a dielectric cap layer 502 is selectively deposited over the device 300. In particular, the dielectric cap layer 502 may be selectively and conformally deposited over the fins 402 including over top and sidewall portions of the nitride layer 312A, over sidewalls of the epitaxial layer portions 308A, over sidewalls of the epitaxial layer portions 310A, and over a portion of sidewalls of the substrate portions 302A (if exposed). However, the dielectric cap layer 502 may not be deposited on a top surface of the STI features 404 disposed between the fins 402. In some embodiments, deposition of the dielectric cap layer 502 results in formation of trenches 504 interposing adjacent fins 402. In some examples, the dielectric cap layer 502 may include SiGe. Alternatively, in some cases, the dielectric cap layer 502 may include SiN, SiCN, SiOCN, or other appropriate material. By way of example, the dielectric cap layer 502 may be deposited by an MBE process, an MOCVD process, an ALD process, and/or other suitable epitaxial growth processes. In some embodiments, the forming of the dielectric cap layer 502 may be omitted. In various embodiments, the dielectric cap layer 502 is a sacrificial layer that is removed at a subsequent processing stage, as described below.

The method 200 then proceeds to block 208 where a dielectric layer is deposited, and a CMP process is performed. Referring to the example of FIGS. 5 and 6, in an embodiment of block 208, a dielectric layer 602 is deposited conformally within the trenches 504 including along sidewalls of the dielectric cap layer 502 and along a top surface of the STI features 404. Thereafter, a dielectric layer 604 is deposited over the dielectric layer 602. In at least some embodiments, the dielectric layers 602, 604 may collectively define a hybrid fin 606. However, in some cases, a hybrid fin may further include a high-κ dielectric layer formed over the dielectric layers 602, 604, for example after recessing of the dielectric layers 602, 604, as discussed below. Generally, and in some embodiments, the dielectric layers 602, 604 may include SiN, SiCN, SiOC, SiOCN, SiOₓ, or other appropriate material. In some examples, the dielectric layer 602 may include a low-κ dielectric layer, and the dielectric layer 604 may include a flowable oxide layer. In various cases, the dielectric layers 602, 604 may be deposited by a CVD process, an ALD process, a PVD process, a spin-coating and baking process, and/or other suitable process. In some examples, after depositing the dielectric layers 602, 604, a CMP process may be performed to remove excess material portions and to planarize a top surface of the device 300.

The method 200 then proceeds to block 210 where a recessing process, a high-K dielectric layer deposition process, and a CMP process are performed. Referring to the example of FIGS. 6 and 7, in an embodiment of block 210, a recessing process is performed to remove top portions of the dielectric layers 602 and 604. In some embodiments, the recessing process may include a dry etching process, a wet etching process, and/or a combination thereof. In some embodiments, a recessing depth is controlled (e.g., by controlling an etching time) to result in a desired recess depth D. In some cases, the recessing process may optionally remove at least part of the dielectric cap layer 502. After performing the recessing process, and in a further embodiment of block 210, a high-K dielectric layer 702 is deposited within trenches formed by the recessing process. In some embodiments, the high-K dielectric layer 702 may include metal oxide, such as HfO₂, ZrO₂, HfAlOₓ, HfSiOₓ, Y₂O₃, Al₂O₃, or another high-K material. The high-K dielectric layer 702 may be deposited by a CVD process, an ALD process, a PVD process, and/or other suitable process. After deposition of the high-K dielectric layer 702, and in a further embodiment of block 210, a CMP process is performed to remove excess material portions and to planarize a top surface of the device 300. In some examples, the CMP process removes a portion of the dielectric cap layer 502 from the top of the fins 402 to expose the nitride layer 312A. Thus, in various cases, a hybrid fin 706 is defined as having a lower portion including the recessed portions of the dielectric layers 602, 604 and an upper portion including the high-K dielectric layer 702. In some examples, a height H1 of the high-K dielectric layer 702 may be about 10-30 nm. It is noted that the height H1 may be defined by the recess depth D, and a height H1 greater than about 30 nm may not provide significant advantage. For example, a recess depth D greater than about 30 nm, and thus a height H1 greater than about 30 nm, could result in the high-K dielectric layer 702 being directly adjacent to channel layers of the device 300 (e.g., the epitaxial layer portions 308A). In such cases, the high-K dielectric layer 702 may cause parasitic coupling between channel layers of adjacent fins, thereby degrading device performance. It is further noted that if the height H1 is less than about 10 nm, the high-K dielectric layer 702 may not be sufficiently thick to endure a subsequent etch process (e.g., the active region isolation etch process). In some cases, the hybrid fins 706 may be alternatively described as a bi-layer dielectric having a high-K upper portion and a low-K lower portion. In some examples, a height ratio of the upper portion to the lower portion may be about 1/20-20/1. The height ratio may be adjusted, for example, by changing the recess depth D (and thus the height H1), as noted above. In some embodiments, the hybrid fins 706 (with the high-K upper portion), or the hybrid fins 606 (without the high-K upper portion) may be used to effectively prevent the undesirable lateral merging of the source/drain epi-layers formed on adjacent fins, as discussed in more detail below. As also shown in FIG. 7, one of the hybrid fins 706 has the width W1 and corresponds to the hybrid fin 106 of FIG. 1, and another of the hybrid fins 706′ has the width W2 and corresponds to the hybrid fin 106′ of FIG. 1.

The method 200 then proceeds to block 212 where a dummy gate structure is formed. While the present discussion is directed to a replacement gate (gate-last) process whereby a dummy gate structure is formed and subsequently replaced, other configurations may be possible. With reference to FIGS. 7, 8, and 9, in an embodiment of block 212, the nitride layer 312A and portions of the dielectric cap layer 502 may initially be etched-back such that top surfaces of the etched-back dielectric cap layer 502 are substantially level with top surfaces of the topmost epitaxial layer portion 310A of the fins 402. In some embodiments, the etch-back of the nitride layer 312A and the portions of the dielectric cap layer 502 may be performed using a wet etch process, a dry etch process, a multiple-step etch process, and/or a combination thereof. After performing the etch-back process, and in a further embodiment of block 212, gate stacks 802 are formed over the fins 402 and over the hybrid fins 706, including over the top surfaces of the etched-back dielectric cap layer 502 and over the top surfaces of the topmost epitaxial layer portion 310A of the fins 402. In an embodiment, the gate stacks 802 are dummy (sacrificial) gate stacks that are subsequently removed and replaced by the final gate stack at a subsequent processing stage of the device 300, as discussed below. The gate stacks 802 may be replaced at a later processing stage by a high-K dielectric layer (HK) and metal gate electrode (MG). In some embodiments, the gate stacks 802 are formed over the substrate 302 and are at least partially disposed over the fins 402 and the hybrid fins 706. The portion of the fins 402 underlying the gate stacks 802 may be referred to as the channel region. The gate stacks 802 may also define a source/drain region of the fins 402, for example, the regions of the fins 402 adjacent to and on opposing sides of the channel region.

In some embodiments, the gate stacks 802 include a dielectric layer 804 and an electrode layer 806. The gate stacks 802 may also include one or more hard mask layers 808, 810. In some embodiments, the hard mask layer 808 may include a nitride layer (e.g., such as SiN), and the hard mask layer 810 may include an oxide layer. In some embodiments, the gate stacks 802 are formed by various process steps such as layer deposition, patterning, etching, as well as other suitable processing steps. In some examples, the layer deposition process includes CVD (including both low-pressure CVD and/or plasma-enhanced CVD), PVD, ALD, thermal oxidation, e-beam evaporation, or other suitable deposition techniques, or a combination thereof. In forming the gate stacks 802 for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dielectric layer 804 includes silicon oxide. Alternatively, or additionally, the dielectric layer 804 may include silicon nitride, a high-K dielectric material or other suitable material. In some embodiments, the electrode layer 806 may include polycrystalline silicon (polysilicon). In some embodiments, the nitride of the hard mask layer 808 includes a pad nitride layer that may include Si₃N₄, silicon oxynitride or silicon carbide. In some embodiments, the oxide of the hard mask layer 810 includes a pad oxide layer that may include SiO₂.

In a further embodiment of block 212, gate spacers 902 are formed on sidewalls of the gate stacks 802. The gate spacers 902 may have a thickness of about 4-10 nm. In some examples, the gate spacers 902 may include a dielectric material such as silicon oxide, silicon nitride, silicon carbide, silicon oxynitride, SiCN, silicon oxycarbide, SiOCN, a low-K material (e.g., with a dielectric constant ‘κ’<7), and/or combinations thereof. In some embodiments, the gate spacers 902 include multiple layers, such as main spacer layers, liner layers, and the like. By way of example, the gate spacers 902 may be formed by conformally depositing a dielectric material over the device 300 using processes such as a CVD process, a subatmospheric CVD (SACVD) process, a flowable CVD process, an ALD process, a PVD process, or other suitable process. Following the conformal deposition of the dielectric material, portions of the dielectric material used to form the gate spacers 902 may be etched-back to expose portions of the fins 402 not covered by the gate stacks 802 (e.g., for example, in source/drain regions). In some examples, the etch-back process may also etch a portion of the high-K dielectric layer 702 of the hybrid fins 706 not covered by the gate stacks 802. In some cases, the etch-back process removes portions of dielectric material used to form the gate spacers 902 along a top surface of the gate stacks 802, thereby exposing the hard mask layer 810 of each of the gate stacks 802. In some embodiments, the etch-back process may include a wet etch process, a dry etch process, a multiple-step etch process, and/or a combination thereof. It is noted that after the etch-back process, the gate spacers 902 remain disposed on sidewalls of the gate stacks 802.

The method 200 then proceeds to block 214 where a source/drain etch process is performed. With reference to FIG. 9, in an embodiment of block 214, a source/drain etch process is performed to remove portions of the fins 402 not covered by the gate stacks 802 (e.g., in source/drain regions) and that were previously exposed (e.g., during the gate spacer 902 etch-back process). In particular, the source/drain etch process may serve to remove the exposed epitaxial layer portions 308A, 310A in source/drain regions of the device 300 to form trenches 904 which expose underlying substrate portions 302A of the fins 402. In some embodiments, the source/drain etch process may include a dry etching process, a wet etching process, and/or a combination thereof.

The method 200 then proceeds to block 216 where inner spacers are formed. With reference to FIGS. 9, 10, and 11, in an embodiment of block 216, inner spacers 1102 are formed. In some embodiments, the formation of the inner spacers 1102 may include a lateral etch (or dielectric recess) of the epitaxial layer portions 310A (SiGe layers) to form recesses 1002, followed by deposition of a dielectric material (including within the recesses 1002), and an etch-back process to form the inner spacers 1102. In some embodiments, the inner spacers 1102 include amorphous silicon. In some examples, the inner spacers 1102 may include silicon oxide, silicon nitride, silicon carbide, silicon oxynitride, SiCN, silicon oxycarbide, SiOCN, a low-κ material (e.g., with a dielectric constant ‘κ’<7), and/or combinations thereof. In various examples, the inner spacers 1102 may extend beneath the gate spacer 902 (formed on sidewalls of the gate stacks 802) while abutting subsequently formed source/drain features, described below.

The method 200 then proceeds to block 218 where source/drain features are formed. With reference to FIGS. 11 and 12, in an embodiment of block 218, source/drain features 1202 are formed in source/drain regions adjacent to and on opposite sides of the gate stacks 802. For example, the source/drain features 1202 may be formed within the trenches 904, over the exposed substrate portions 302A and in contact with the adjacent inner spacers 1102 and the semiconductor channel layers (the epitaxial layer portions 308A). In some embodiments, the source/drain features 1202 are formed by epitaxially growing a semiconductor material layer in the source/drain regions. In various embodiments, the semiconductor material layer grown to form the source/drain features 1202 may include Ge, Si, GaAs, AlGaAs, SiGe, GaAsP, SiP, or other suitable material. The source/drain features 1202 may be formed by one or more epitaxial (epi) processes. In some embodiments, the source/drain features 1202 may be in-situ doped during the epi process. For example, in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 1202 are not in-situ doped, and instead an implantation process is performed to dope the source/drain features 1202. In some embodiments, formation of the source/drain features 1202 may be performed in separate processing sequences for each of N-type and P-type source/drain features. As illustrated in FIG. 12, the hybrid fin 706, which may have a partially etched-back high-K dielectric layer 702, effectively prevents the undesirable lateral merging of the source/drain features 1202 formed on adjacent fins 402.

After forming the source/drain features 1202, as shown in the cross-sectional view of FIG. 13A which is taken along the line A-A of the semiconductor device 300 in FIG. 12 (i.e., an extending direction of the fin 402), the gate stack 802 may be across the fin 402 and the source/drain features 1202 may be formed at opposite sides of the gate stack 802. As shown in the cross-sectional view of FIG. 13B which is taken along the line B-B of the semiconductor device 300 in FIG. 12 (i.e., a parallel direction of the gate stacks 802), the hybrid fin 706 may be formed on the STI feature 404, and the high-K dielectric layer 702 of the hybrid fin 706 may protrude from or exposed by the top surface of the source/drain features 1202. As shown in the cross-sectional view of FIG. 13C which is taken along the line C-C of the semiconductor device 300 in FIG. 12 (i.e., an extending direction of the hybrid fin 706), the gate stack 802 may be across the hybrid fin 706 and a portion of the high-κ dielectric layer 702 uncovered by the gate stack 802 may cover the dielectric layer 604.

The method 200 then proceeds to block 220 where a high-κ etching process is performed. With reference to FIGS. 13A-13C and FIGS. 14A-14C, in an embodiment of block 220, a high-κ etching process is performed to remove a portion of the high-κ dielectric layer 702 uncovered by the gate stacks 802, so that the remaining high-κ dielectric layer 702A is formed directly under the gate stacks 802. In this case, as shown in FIG. 14B, the dielectric layers 602 and 604 uncovered by the gate stacks 802 are exposed. In particular, the high-κ etching process may include performing an anisotropic etching step and then performing an isotropic etching step. The anisotropic etching step may be performed by using the gate spacer 902 and the gate stacks 802 as a mask to remove the high-κ dielectric layer 702 uncovered by the gate spacer 902 and the gate stacks 802, thereby exposing the top surface of the dielectric layer 604. In some embodiments, the anisotropic etching step may include using an etchant of BCl₃, Ar, or a combination thereof. In this case, the high-κ dielectric layer 702 and the source/drain features 1202 (or the dielectric layer 604) have different etch selectivities in the anisotropic etching step. That is, the high-κ dielectric layer 702 may have a greater etching rate than that of the source/drain features 1202 in the anisotropic etching step. After performing the anisotropic etching step, the isotropic etching step may be performed to laterally etch (or trim or recess) the high-κ dielectric layer 702 directly under the gate spacer 902, so that a sidewall 702s of the high-κ dielectric layer 702A may be concave from a sidewall 902s of the gate spacer 902. That is, the sidewall 702s of the high-κ dielectric layer 702A may be spaced from the sidewall 902s of the gate spacer 902 by a non-zero distance. In some embodiments, the isotropic etching step may include using an etchant of NF₃, H₂, BCl₃, or a combination thereof. In this case, the high-κ dielectric layer 702 and the source/drain features 1202 (or the dielectric layer 604) have different etch selectivities in the isotropic etching step. That is, the high-κ dielectric layer 702 may have a greater etching rate than that of the source/drain features 1202 in the isotropic etching step. In the present embodiment, the etching rate of the high-κ dielectric layer 702 may be about 1 nm/min in the isotropic etching step. After performing the isotropic etching step, as shown in FIG. 14C, the sidewall 702s of the high-κ dielectric layer 702A is concave from the sidewall 902s of the gate spacer 902, thus an opening 1405 with a wider lower portion (or wider lower width) and a narrower upper portion (or narrower upper width) may be formed between adjacent two gate stacks 802. In some embodiments, the sidewall 702s of the high-κ dielectric layer 702A may be aligned with the sidewall 802s of the corresponding gate stack 802.

The method 200 then proceeds to block 222 where an inter-layer dielectric (ILD) layer is formed and a CMP process is performed. With reference to FIGS. 15A-15C, in an embodiment of block 222, an ILD layer 1502 is formed over the device 300. In some embodiments, a contact etch stop layer (CESL) 1504 is formed over the device 300 prior to forming the ILD layer 1502. In some examples, the CESL 1504 includes a silicon nitride layer, silicon oxide layer, a silicon oxynitride layer, and/or other materials known in the art. The CESL 1504 may be formed by a plasma-enhanced chemical vapor deposition (PECVD) process and/or other suitable deposition or oxidation processes. In some embodiments, the ILD layer 1502 includes materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. The ILD layer 1502 may be deposited by a PECVD process or other suitable deposition technique. In some embodiments, after formation of the ILD layer 1502, the device 300 may be subject to a high thermal budget process to anneal the ILD layer 1502.

In a further embodiment of block 222, and after depositing the ILD layer 1502 (and/or the CESL 1504 or other dielectric layers), a planarization process may be performed to expose a top surface of the gate stacks 802. For example, a planarization process includes a CMP process which removes portions of the ILD layer 1302 (and CESL 1304, if present) overlying the gate stacks 802 and planarizes a top surface of the device 300. In addition, the CMP process may remove the hard mask layers 808, 810 overlying the gate stacks 802 to expose the underlying electrode layer 806, such as a polysilicon electrode layer, of the dummy gates. After the CMP process, the top surface of the electrode layer 806 may be substantially level with the top surface of the ILD layer 1502. In addition, since the ILD layer 1502 is filled in the opening 1405 (FIG. 14C) between adjacent two gate stacks 802, the ILD layer 1502 may present an inverted T shape in the cross-section of FIG. 15C.

The method 200 proceeds to block 224 where a gate replacement process is performed. Referring to the example of FIGS. 15A-15C and FIGS. 16A-16C, in an embodiment of block 224, a gate replacement process is performed to form a gate structure 1602 on the device 300. In particular, the electrode layer 806 and the dielectric layer 804 in regions over the fins 402 may be removed by a suitable etching process, thereby exposing underlying epitaxial layer portions 310A of the fins 402. In various embodiments, the etching process may include a wet etch, a dry etch, a multiple-step etch process, or a combination thereof. After removal of the electrode layer 806 and the dielectric layer 804, and in a further embodiment of block 224, a selective removal of the epitaxial layer portions 310A between the channel regions 308A of the fins 402 is performed. In various examples, the SiGe layers (including the etched-back dielectric cap layer 502 (FIG. 7) and the epitaxial layer portions 310A) are removed from the exposed fins 402 using a selective wet etching process. In some embodiments, the selective wet etching includes ammonia and/or ozone. As merely one example, the selective wet etching includes tetra-methyl ammonium hydroxide. (TMAH). In an embodiment, the etched-back dielectric cap layer 502 and the epitaxial layer portions 310A are SiGe and the epitaxial layer portions 308A are silicon, allowing for the selective removal of the SiGe layers. It should be noted after selective removal of the SiGe layers, gaps may be formed between the adjacent semiconductor channel layers in the channel region (e.g., gaps between epitaxial layer portions 308A). In some examples, selective removal of the SiGe layers, as described above, may be referred to as a semiconductor channel layer release process.

After removal of the epitaxial layer portions 310A, and in a further embodiment of block 224, a gate structure 1602 is formed over the device 300. The gate structure 1602 may include a high-K/metal gate stack, however other compositions are possible. In some embodiments, the gate structure 1602 may form the gate associated with the multi-channels provided by the plurality of exposed semiconductor channel layers (epitaxial layer portions 308A, now having gaps there between) in the channel region of the device 300. Generally, the formation of the high-K/metal gate stack may include depositions to form various gate materials, one or more liner layers, and one or more CMP processes to remove excessive gate materials and thereby planarize a top surface of the device 300, among other processes, as described below.

In some embodiments, a gate dielectric 1604 may initially be formed within the trenches of the device 300 provided by the removal of the dummy gate and/or by the release of the semiconductor channel layers, as described above. In various embodiments, the gate dielectric 1604 includes an interfacial layer (IL) and a high-κ gate dielectric layer formed over the interfacial layer. In some embodiments, the gate dielectric 1604 has a total thickness of about 1-5 nm. High-K gate dielectrics, as used and described herein, include dielectric materials having a high dielectric constant, for example, greater than that of thermal silicon oxide (about 3.9).

In some embodiments, the interfacial layer of the gate dielectric 1604 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-κ gate dielectric layer of the gate dielectric 1604 may include a high-κ dielectric layer such as hafnium oxide (HfO₂). Alternatively, the high-κ gate dielectric layer may include other high-κ dielectrics, such as TiO2, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfSiO, (Ba,Sr)TiO₃ (BST), Al₂O₃, Si₃N₄, oxynitrides (SiON), combinations thereof, or other suitable material. The high-κ gate dielectric layer may be formed by ALD, physical vapor deposition (PVD), CVD, oxidation, and/or other suitable methods.

In a further embodiment of block 224, a metal gate including a metal layer 1606 is formed over the gate dielectric 1604 of the device 300. In some embodiments, the metal layer 1606 may initially be deposited over the device 300 and etched-back, as discussed below, to form the metal layer 1606 as shown in FIG. 16A. The metal layer 1606 may include a metal, metal alloy, or metal silicide. In some embodiments, the metal layer 1606 may include a single layer or alternatively a multi-layer structure, such as various combinations of a metal layer with a selected work function to enhance the device performance (work function metal layer), a liner layer, a wetting layer, an adhesion layer, a metal alloy, or a metal silicide. By way of example, the metal layer 1606 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer 1606 may be formed by ALD, PVD, CVD, e-beam evaporation, or other suitable process. Further, the metal layer 1606 may be formed separately for N-type and P-type transistors which may use different metal layers. In addition, the metal layer 1606 may provide an N-type or P-type work function, may serve as a transistor (e.g., GAA transistor) gate electrode, and in at least some embodiments, the metal layer 1606 may include a polysilicon layer. With respect to the GAA device shown and discussed, the gate structure includes portions that interpose each of the epitaxial layer portions 308A, which each provide semiconductor channel layers for the device 300. In the present embodiment, the epitaxial layer portions 308A stacked on the substrate 302 may be referred to nanosheet stacks 402 for GAA device.

After formation of the metal layer 1606, and in a further embodiment of block 224, a planarization process may be performed to expose the top surface of the ILD layer 1302. For example, a planarization process includes a CMP process which removes portions of the metal layer 1606 overlying the ILD layer 1302 and planarizes a top surface of the device 300. After the CMP process, the top surface of the metal layer 1606 may be substantially level with the top surface of the ILD layer 1502.

The method 200 proceeds to block 226 where source/drain contact openings are formed. Referring to the example of FIGS. 16A-16C and FIGS. 17A-17C, in an embodiment of block 226, source/drain contact openings 1705 are formed in the ILD layer 1502 and the CESL 1504 to expose the underlying source/drain features 1202. In particular, the formation of the source/drain contact openings 1705 includes etching the ILD layer 1502 to expose the underlying portions of the CESL 1504, and then etching the exposed portions of the CESL 1504 to reveal the source/drain features 1202. In some embodiments, the etching process of removing the ILD layer 1502 and the exposed portions of the CESL 1504 may include a wet etch, a dry etch, a multiple-step etch process, or a combination thereof.

The method 200 proceeds to block 228 where source/drain contact plugs are formed. Referring to the example of FIGS. 17A-17C and FIGS. 18A-18C, in an embodiment of block 228, source/drain contact plugs 1802 are formed in the source/drain contact openings 1705 to contact the source/drain features 1202. Specifically, a metal layer (e.g., Ti layer) is deposited and extending into the contact openings 1705. An anneal process is then performed to react the metal layer with the top portion of the source/drain features 1202 to form silicide regions, as shown in FIGS. 18A and 18B. Next, the unreacted metal layer may be removed while the previously formed metal silicide layer may be left as not removed. A filling metallic material such as tungsten, cobalt, or the like, is then filled into the contact openings 1705, followed by a planarization to remove excess materials, resulting in the source/drain contact plugs 1802. Accordingly, one of the source/drain contact plugs 1802 may include a metal silicide layer 1804 and the filling metallic material 1806 over the metal silicide layer 1804. In some embodiments, a liner or barrier layer (not shown) may be formed between the source/drain contact plugs 1802 and the ILD layer 1502. The liner or barrier layer may include metal nitride, such as TiN, TaN, or other appropriate barrier material.

Generally, the semiconductor device 300 may undergo further processing to form various features and regions known in the art. For example, subsequent processing may form contact openings, contact metal, as well as various contacts/vias/lines and multilayer interconnect features (e.g., metal layers and interlayer dielectrics) on the substrate 302, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200. Further, while the method 200 has been shown and described as including the device 300 having a GAA transistor, it will be understood that other device configurations are possible. In some embodiments, the method 200 may be used to fabricate FinFET devices or other multi-gate devices.

With respect to the description provided herein, disclosed are methods and structures for providing a hybrid fin structure, where the hybrid fin structure exposed by the metal gate is free of a high-κ dielectric material to decrease the parasitic capacitance between the metal gate and the adjacent source/drain contact plug, thereby enhancing the device performance. In some embodiments, as shown in FIG. 18C, the semiconductor device 300 includes a hybrid fin structure 706′, agate structure 1602, and a contact plug 1802. The hybrid fin structure 706′ may include a main body portion 706A and a protrusion portion 706B disposed on the main body portion 706A. In some embodiments, the protrusion portion 706B has a dielectric constant greater than a dielectric constant of the main body portion 706A which including the dielectric layers 602 and 604. The gate structure 1602 may be across the protrusion portion 706B of the hybrid fin structure 706′. The contact plug 1802 may be disposed aside the gate structure 1602 and contacts the main body portion 706A of the hybrid fin structure 706′. It can be seen from FIG. 18C that the spacer structure laterally between the gate structure 1602 and adjacent contact plug 1802 may include the gate spacer 902, a portion of the ILD layer 1502, and a portion of the CESL 1504. The gate spacer 902 may cover the sidewall of the gate structure 1602; the portion of the CESL 1504 may extend between the gate spacer 902 and the contact plug 1802, and further covers the sidewall of the protrusion portion (or high-κ dielectric layer) 706B; and the portion of the ILD layer 1502 may extend between the CESL 1504 and the contact plug 1802. In such embodiment, the spacer structure (902/1502/1504) has a dielectric constant lower than a dielectric constant of the protrusion portion (or high-κ dielectric layer) 706B. Accordingly, the undesirable parasitic capacitance between the gate structure 1602 and the adjacent source/drain contact plug 1802 may be reduced, thereby enhancing the device performance.

According to some embodiments, a semiconductor device includes at least two active strip regions, a hybrid fin structure, and a gate stack. The hybrid fin structure is disposed between the at least two active strip regions. The gate stack is across the at least two active strip regions and the hybrid fin structure. A portion of the hybrid fin structure exposed by the gate stack is free of a high dielectric constant material.

According to some embodiments, a method of forming a semiconductor device includes: forming a plurality of fin structures extending along a first direction, wherein the plurality of fin structures comprises a hybrid fin structure with a high dielectric constant top; forming a plurality of gate stacks extending along a second direction and across the plurality of fin structures; and performing an etching process to remove the high dielectric constant top uncovered by the plurality of gate stacks, so that a high dielectric constant (high-κ) dielectric layer is formed directly under the plurality of gate stacks.

According to some embodiments, a semiconductor device includes a hybrid fin structure, a gate stack, and a contact plug. The hybrid fin structure includes a main body portion and a protrusion portion disposed on the main body portion. The protrusion portion has a dielectric constant greater than a dielectric constant of the main body portion. The gate stack is across the protrusion portion of the hybrid fin structure. The contact plug is disposed aside the gate stack and contacts the main body portion of the hybrid fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
at least two active strip regions;
a hybrid fin structure disposed between the at least two active strip regions; and
a gate stack across the at least two active strip regions and the hybrid fin structure, wherein a portion of the hybrid fin structure exposed by the gate stack is free of a high dielectric constant material.

2. The semiconductor device of claim 1, wherein the hybrid fin structure comprises:
a first dielectric layer;
a second dielectric layer disposed on the first dielectric layer; and
a high dielectric constant (high-κ) dielectric layer vertically disposed between the second dielectric layer and the gate stack, wherein the high-κ dielectric layer has a dielectric constant greater than a dielectric constant of the first and second dielectric layers.

3. The semiconductor device of claim 2, wherein a sidewall of the high-κ dielectric layer is aligned with a sidewall of the gate stack.

4. The semiconductor device of claim 2, further comprising:
a gate spacer overlying a sidewall of the gate stack, wherein a sidewall of the high-κ dielectric layer is concave from a sidewall of the gate spacer, so that the sidewall of the high-κ dielectric layer is spaced from the sidewall of the gate spacer by a non-zero distance.

5. The semiconductor device of claim 2, further comprising:
source/drain features disposed on the at least two active strip regions at opposite sides of the gate stack; and
source/drain contact plugs disposed on the source/drain features, wherein a portion of the source/drain contact plugs extends between adjacent two gate stacks, and the high-κ dielectric layer is not included under the source/drain contact plugs.

6. The semiconductor device of claim 5, further comprising:
an etch stop layer extending between the source/drain contact plugs and the gate stack, and conformally covering a sidewall of the high-κ dielectric layer covered by the gate stack; and
an inter-layer dielectric (ILD) layer disposed on the etch stop layer, wherein a portion of the ILD layer extends between the source/drain contact plugs and the gate stack.

7. The semiconductor device of claim 1, wherein each active fin structure comprises a plurality of semiconductor nanosheets vertically stacked with each other, and the gate stack wraps the plurality of semiconductor nanosheets.

8. The semiconductor device of claim 1, wherein the at least two active strip regions and the hybrid fin structure extend along a first direction, the gate stack extends along a second direction, and the first direction is substantially perpendicular to the second direction.

9. A method of forming a semiconductor device, comprising:
forming a plurality of fin structures extending along a first direction, wherein the plurality of fin structures comprises a hybrid fin structure with a high dielectric constant top;
forming a plurality of gate stacks extending along a second direction and across the plurality of fin structures; and
performing an etching process to remove the high dielectric constant top uncovered by the plurality of gate stacks, so that a high dielectric constant (high-κ) dielectric layer is formed directly under the plurality of gate stack.

10. The method of claim 9, wherein before performing the etching process, the method further comprises forming gate spacers on sidewalls of the plurality of gate stacks.

11. The method of claim 10, wherein the performing the etching process comprises:
performing an anisotropic etching step by using the gate spacers and the plurality of gate stacks as a mask to remove the high dielectric constant top of the hybrid fin structure uncovered by the gate spacers and the plurality of gate stacks; and
performing an isotropic etching step to laterally etch the high dielectric constant top directly under the gate spacers, so that a sidewall of the high-κ dielectric layer is concave from a sidewall of a corresponding gate spacer.

12. The method of claim 11, wherein the anisotropic etching step comprises using an etchant of BCl₃, Ar, or a combination thereof.

13. The method of claim 11, wherein the isotropic etching step comprises using an etchant of NF₃, H₂, BCl₃, or a combination thereof.

14. The method of claim 9, wherein after performing the etching process, the hybrid fin structure comprises:
a first dielectric layer;
a second dielectric layer formed on the first dielectric layer; and
the high-κ dielectric layer vertically formed between the second dielectric layer and a corresponding gate stack, wherein the high-κ dielectric layer has a dielectric constant greater than a dielectric constant of the first and second dielectric layers.

15. The method of claim 14, wherein after performing the etching process, a top surface of the second dielectric layer is exposed, and an opening with a wider lower portion and a narrower upper portion is formed between adjacent two gate stacks.

16. A semiconductor device, comprising:
a hybrid fin structure comprising a main body portion and a protrusion portion disposed on the main body portion, wherein the protrusion portion has a dielectric constant greater than a dielectric constant of the main body portion;
a gate stack across the protrusion portion of the hybrid fin structure; and
a contact plug disposed aside the gate stack and contacting the main body portion of the hybrid fin structure.

17. The semiconductor device of claim 16, wherein a sidewall of the protrusion portion is aligned with a sidewall of the gate stack.

18. The semiconductor device of claim 16, further comprising:
a gate spacer overlying a sidewall of the gate stack, wherein a sidewall of the protrusion portion is concave from a sidewall of the gate spacer, so that the sidewall of the protrusion portion is spaced from the sidewall of the gate spacer by a non-zero distance.

19. The semiconductor device of claim 16, wherein a portion of the hybrid fin structure exposed by the gate stack is free of a high dielectric constant material.

20. The semiconductor device of claim 16, further comprising at least two active fin structures, wherein the hybrid fin structure is disposed between the at least two active fin structures, and each active fin structure comprises a plurality of semiconductor nanosheets vertically stacked with each other.
